(19) United States
(12) Patent Application Publication
(10) Pub. No.: US 2026/0114153 A1
(43) Pub. Date: Apr. 23, 2026

(54) Display Apparatus

(71) Applicant: LG Display Co., Ltd., Seoul (KR)

(72) Inventors: Gyu-Hyeong HAN, Paju-si (KR); Hun-Bae IM, Paju-si (KR); Yoon-Seok LEE, Paju-si (KR); Eon-Ho CHA, Paju-si (KR); Sang-Bin SHIN, Paju-si (KR); Dae-Hee HAN, Paju-si (KR)

(21) Appl. No.: 18/927,110

(22) Filed: Oct. 25, 2024

(30) Foreign Application Priority Data
Feb. 23, 2024 (KR) 10-2024-0026492

(51) Int. Cl. H10K 59/80; H10K 59/122

(52) U.S. Cl. CPC H10K 59/873; H10K 59/122; H10K 59/80515; H10K 59/80521

(57) ABSTRACT

A display apparatus includes a substrate including a plurality of subpixels. The display apparatus includes a bank layer arranged to surround each of the plurality of subpixels. The display apparatus includes a light emitting element disposed in the subpixel. The display apparatus includes an encapsulation layer encapsulating the light emitting element. The display apparatus includes at least one passage formed at an upper surface of the bank layer between adjacent subpixels and through which an organic material for forming the encapsulation layer flows between the adjacent subpixels.

### CROSS-REFERENCE TO RELATED APPLICATIONS

The present application claims the priority benefit of Korean Patent Application No. 10-2024-0026492 filed in Korea on Feb. 23, 2024, which is hereby incorporated by reference in its entirety for all purposes as if fully set forth herein.

### BACKGROUND

### Technical Field

The present disclosure relates to a display apparatus in which spot defects caused by unevenness of an encapsulation layer are improved.

### Description of the Related Art

Recently, with development of multimedia, importance of display apparatuses is increasing. In response to this, flat panel display apparatuses such as liquid crystal display apparatuses, plasma display apparatuses, and organic electroluminescent display apparatuses are being commercialized. Among these display apparatuses, organic electroluminescent display apparatuses are currently widely used because they have high response speed, high brightness, and good viewing angle.

The organic electroluminescent display apparatus is provided with an organic light emitting element in each of a plurality of subpixels, and displays an image as the organic light emitting elements emit light. Generally, the organic light emitting element is vulnerable to moisture or oxygen, so an encapsulation layer is formed to encapsulate the organic light emitting element to prevent moisture or oxygen from penetrating from an outside.

### BRIEF SUMMARY

The inventors of the present disclosure have appreciated that, when the encapsulation layer is not uniformly applied over the entire display apparatus, light refraction occurs due to thickness deviation, and this light refraction causes spots to appear on a screen. Various embodiments of the present disclosure as provided by the inventors address one or more problems in the related art. For example, an advantage of the present disclosure is to provide a display apparatus in which an encapsulation layer can be formed with a uniform thickness over an entire region by forming grooves at an upper surface of a bank layer between adjacent subpixels.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display apparatus includes: a substrate including a plurality of subpixels; a bank layer arranged to surround each of the plurality of subpixels; a light emitting element disposed in the subpixel; an encapsulation layer encapsulating the light emitting element; and at least one passage formed at an upper surface of the bank layer between adjacent subpixels and through which an organic material for forming the encapsulation layer flows between the adjacent subpixels.

It is to be understood that both the foregoing general description and the following detailed description are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a schematic block diagram of a display apparatus according to the present disclosure;

FIG. 2 is a schematic block diagram of a subpixel of a display apparatus according to the present disclosure;

FIG. 3 is a circuit diagram illustrating an example of a subpixel of a display apparatus according to the present disclosure;

FIG. 4 is a plan view schematically illustrating a structure of a display apparatus according to the present disclosure;

FIG. 5 is a plan view schematically illustrating a structure of a pixel of a display apparatus according to the present disclosure;

FIG. 6 is a cross-sectional of a display apparatus according to a first embodiment of the present disclosure;

FIG. 7A is a view illustrating that an organic material for encapsulation spreads in a display apparatus without a groove formed at an upper surface of a bank layer;

FIG. 7B is a view illustrating that an organic material for encapsulation spreads in a display apparatus with a groove formed at an upper surface of a bank layer according to a first embodiment of the present disclosure;

FIG. 8 is a cross-sectional view of a display apparatus according to a second embodiment of the present disclosure; and

FIG. 9 is a cross-sectional view enlarging a part of a light emitting element of a display apparatus according to a second embodiment of the present disclosure.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure can be defined by the scope of the claims.

The shapes, sizes, dimensions (e.g., length, width, height, thickness, radius, diameter, area, etc.), proportions, angles, numbers, and the like disclosed in the drawings for explaining the embodiments of the present disclosure are illustrative, and the present disclosure is not limited to the illustrated matters.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout the description. Furthermore, in describing the present disclosure, if it is determined that a detailed description of the related known technology unnecessarily obscure the subject matter of the present disclosure, the detailed description thereof can be omitted. When terms such as “include,” “have,” “comprise,” “contain,” “constitute,” “make up of,” “formed of,” and “consist of”, and the like are used in this disclosure, other parts can be added unless ‘only’ is used. When a component is expressed in the singular, cases including the plural are included unless specific statement is described.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In interpreting the components, even if there is no separate explicit description, it is interpreted as including a margin range.

Where positional relationships are described, for example, where the positional relationship between two parts is described using “on,” “over,” “under,” “above,” “below,” “beneath,” “near,” “close to,” or “adjacent to,” “beside,” “next,” or the like, one or more other parts may be located between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,”“lower,”and the like refer to an arbitrary frame of reference.

In the case of a description of a temporal relationship, for example, when a temporal precedence is described as ‘after’, ‘following’, ‘before’, and the like, cases that are not continuous can be included unless ‘directly’ or ‘immediately’ is used.

Respective features of various embodiments of the present disclosure can be partially or wholly connected to or combined with each other and can be technically interlocked and driven variously, and respective embodiments can be independently implemented from each other or can be implemented together with a related relationship.

In describing components of the present disclosure, terms such as first, second, A, B, (a), (b) and the like can be used. These terms are only for distinguishing the components from other components, and an essence, order, order, or number of the components is not limited by the terms. Further, when it is described that a component is “connected”, “coupled” or “contact” to another component, the component can be directly connected or contact the another component, but it should be understood that other component can be “interposed” between the components, or the components can be “connected”, “coupled”or “contact”through other component.

The term “at least one” should be understood to include all combinations of one or more of related elements. For example, the term of “at least one of first, second and third elements” may include all combinations of two or more of the first, second and third elements as well as the first, second or third element.

In this disclosure, a “display apparatus” can include a narrowly defined display apparatus, such as a display module or the like, including a display panel and a driving portion for driving the display panel. Furthermore, the “display apparatus” can include a complete product or final product which is a notebook computer, a television, a computer monitor, an automotive device or equipment display including other type of vehicle, or a set electronic device or set device or set apparatus such as a mobile electronic device which is a smart phone, an electronic pad or the like, including the display module or the like.

Therefore, the display apparatus of this disclosure can include a narrowly defined display apparatus itself such as the display module or the like, and/or an application product or a set device that is an end-user device, including the display module or the like.

The display panel of the present disclosure may include all kinds of display panels such as a liquid crystal display panel, an organic light emitting diode display panel,, an inorganic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor, and the present disclosure is not limited thereto.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, embodiments of the present disclosure are described in detail with reference to the drawings.

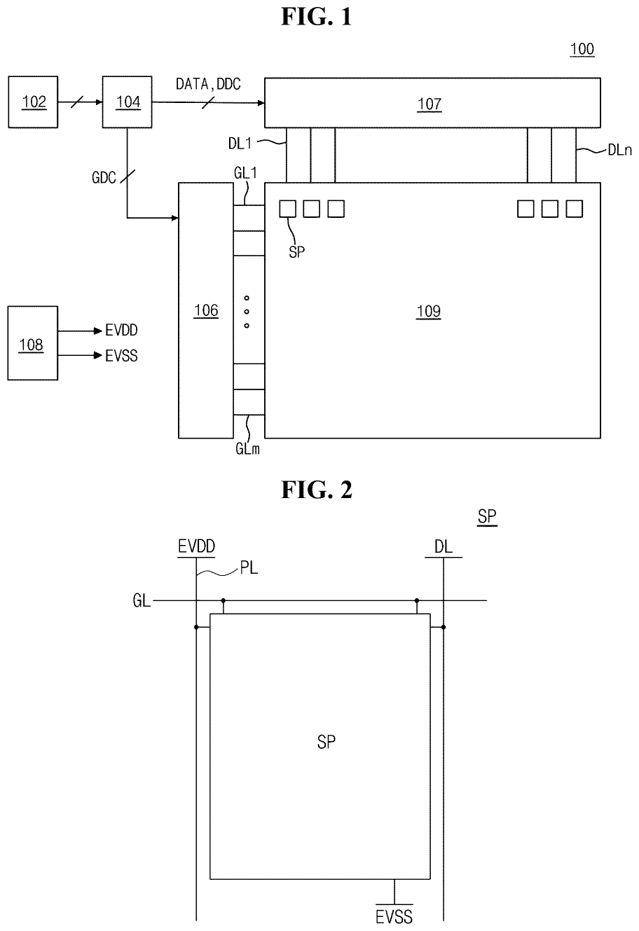

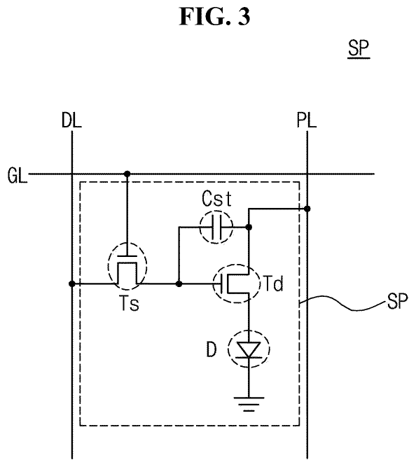

FIG. 1 is a schematic block diagram of a display apparatus according to the present disclosure, and FIG. 2 is a schematic block diagram of a subpixel of FIG. 1.

As illustrated in FIG. 1, the display apparatus 100 includes an image processing portion 102, a timing control portion 104, a gate driving portion 106, a data driving portion 107, a power supply portion 108, a display panel 109, and the like. The exemplary embodiments of the present disclosure are not limited thereto. In addition, all the components of each display apparatus according to all embodiments of the present disclosure are operatively coupled and configured.

The image processing portion 102 outputs image data supplied from an outside and driving signals for driving various components of the display apparatus 100. For example, the driving signals output from the image processing portion 102 may include a data enable signal, a vertical synchronization signal, a horizontal synchronization signal, a clock signal, and the like, for example, from an external device such as a host system. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel.

The timing control portion 104 receives the image data and the driving signals from the image processing portion 102. The timing control portion 104 generates and outputs a gate control signal (or gate timing control signal) GDC for controlling operation timing of the gate driving portion 106 and a data control signal (or data timing control signal) DDC for controlling operation timing of the data driving portion 107 based on the driving signals from the image processing portion 102.

The gate driving portion 106 outputs scan signals (or gate signals) to the display panel 109 in response to the gate control signal GDC supplied from the timing control portion 104. For example, the gate driving portion 106 may be a circuit for driving a plurality of gate lines GL1 to GLm, and can supply scan signals to the plurality of gate lines GL1 to GLm. The gate driving portion 106 outputs the scan signals through a plurality of gate lines GL1 to GLm. At this time, the gate driving portion 106 may be formed in a form of an IC (Integrated Circuit), but not limited thereto. The gate driving portion 106 includes various gate driving circuits, and the gate driving circuits may be formed directly on a substrate of the display panel 109. In this case, the gate driving portion 106 may be a GIP (Gate-In-Panel) type driving portion, but is not limited thereto.

As another example, the gate driving portion 106 may be configured with at least one gate IC. As an example, the gate driving portion 106 may be connected to the display panel 109, for example, in a tape automated bonding (TAB) method, a chip on glass (COG) method, a chip on panel (COP) method, or a chip on film (COF) method, without being limited thereto.

The data driving portion 107 responds to the data control signal DDC from the timing control portion 104 to output data voltages to the display panel 109. The data driving portion 107 samples and latches digital data signals DATA supplied from the timing control portion 104 and converts it into analog data voltages based on gamma voltages. For example, the data driving portion 107 may be a circuit for driving the plurality of data lines DL1 to DLn, and can supply data signals to the plurality of data lines DL1 to DLn. The data driving portion 107 outputs the data voltages through a plurality of data lines DL1 to DLn. At this time, the data driving portion 107 may be formed in a form of an IC (Integrated Circuit), but not limited thereto.

The power supply portion 108 outputs a high-potential voltage EVDD and a low-potential voltage EVSS, on the basis of an external input voltage supplied from the outside, and supplies them to the display panel 109. The high-potential voltage EVDD is supplied to the display panel 109 through a first power line (PL of FIG. 3), and the low-potential voltage EVSS is supplied to the display panel 109 through a second power line. At this time, the power supplying portion 108 may generate and output a voltage needed for driving of the gate driving portion 106, a voltage needed for driving of the data driving portion 107, and a voltage needed for driving of a memory, in addition to the high potential voltage EVDD and the low potential voltage EVSS, for example, other voltages output from the power supply portion 108 may be output to the gate driving portion 106 and/or the data driving portion 107 and used for driving them.

The display panel 109 displays an image in response to the data voltages and scan signals supplied from the data driving portion 107 and the gate driving portion 106, and the voltages supplied from the power supply portion 108.

The display panel 109 includes a plurality of subpixels SP to display an image. The plurality of subpixels SP is a minimum unit which configures the display region and n subpixels SP form one pixel. Each of the plurality of subpixels SP may emit light having different wavelengths from each other. The plurality of subpixels may include first to third subpixels which emit different color light from each other. For example, the subpixels SP may include a red subpixel, a green subpixel, and a blue subpixel, or may include a white subpixel, a red subpixel, a green subpixel, and a blue subpixel. At this time, the white, red, green, and blue subpixels may all be formed with the same area, but may be formed with different areas. Embodiments are not limited thereto. As an example, the subpixel SP of other colors such as magenta, cyan, or yellow may be alternatively or additionally included, without being limited thereto.

For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red subpixel, the blue subpixel, and the green subpixel may be sequentially disposed along a row direction, or the red subpixel, the blue subpixel, the green subpixel and the white subpixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

In addition, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

As illustrated in FIG. 2, one subpixel SP may be connected to the gate line GL, the data line DL, the first power line PL, and the second power line. The subpixel SP may include a plurality of thin film transistors and a storage capacitor depending on a configuration of a pixel circuit. For example, the subpixel SP may be configured with a 2T1C structure in which two transistors and one capacitor is formed in the subpixel SP, but not limited thereto. The subpixel SP may be configured with 3T1C, 4T1C, 5T1C, 6T1C, 7T1C, 3T2C, 4T2C, 5T2C, 6T2C, 7T2C, 8T2C, etc. However, the present disclosure is not limited thereto, and more or less transistors and capacitors could be included in the subpixel SP.

FIG. 3 is a circuit diagram illustrating an example of a subpixel of a display apparatus according to the present disclosure.

As illustrated in FIG. 3, the display apparatus according to the present disclosure includes the gate line GL, the data line DL, and the power line PL that cross with each other to define the subpixel SP.

A switching transistor Ts, a driving transistor Td, a storage capacitor Cst, and a light emitting element (or light emitting diode) D are disposed in the subpixel SP. The switching transistor Ts is connected to the gate line GL and the data line DL, in particular, the gate electrode of the switching thin film transistor Ts is connected to the gate line GL, and the drain electrode of the switching thin film transistor Ts is connected to the data line DL, the driving transistor Td and the storage capacitor Cst are connected between the switching transistor Ts and the power line PL, and the light emitting element D is connected to the driving transistor Td.

In the display apparatus having this structure, when the switching transistor Ts is turned on according to the scan signal applied to the gate line GL, the data signal applied to the data line DL is supplied to a gate electrode of the driving transistor Td and one electrode of the storage capacitor Cst through the switching transistor Ts.

The driving transistor Td is turned on according to the data signal applied to the gate electrode thereof, and as a result, a current proportional to the data signal flows from the power line PL through the driving transistor Td to the light emitting element D, and the light emitting element D emits light with a brightness proportional to the current flowing through the driving transistor Td.

At this time, the storage capacitor Cst is charged with a voltage proportional to the data signal, so that the voltage of the gate electrode of the driving transistor Td is maintained constant during one frame.

In the drawing, only two transistors Td and Ts and one capacitor Cst are provided in the subpixel SP, but this not limited thereto, and three or more transistors and two or more capacitors may be provided.

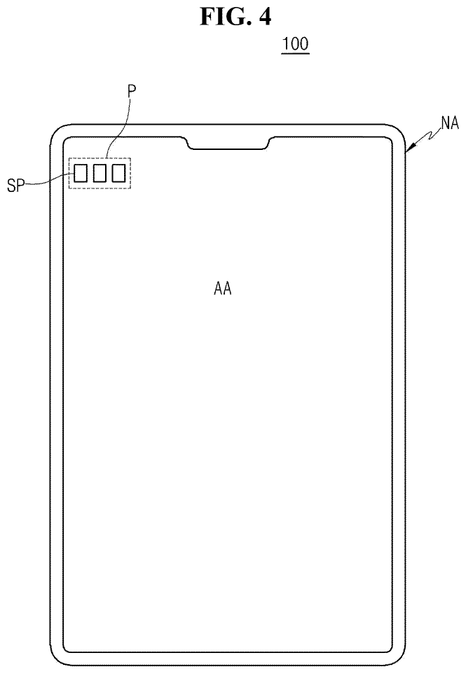

FIG. 4 is a plan view schematically illustrating a structure of a display apparatus according to the present disclosure.

As illustrated in FIG. 4, the display apparatus 100 according to the present disclosure includes a display region AA where an actual image is displayed, and a non-display region NA adjacent to the display region AA, for example, arranged outside the display region AA. The non-display region NA may refer to an area outside of the display region AA. Several types of signal lines may be disposed in the non-display region NA, and several types of driving circuits may be connected thereto. At least a portion of the non-display region NA may be bent to be invisible from the front surface of the display apparatus 100 or may be covered by a case or housing (not shown) of the display apparatus 100. The non-display region NA may be also referred to as an edge area or a bezel area. For example, the non-display region NA may fully or partially surround the display region AA, for example, the non-display region NA may be adjacent to the display region AA and disposed at the outside from the display region AA.

A plurality of pixels P are arranged in the display region AA, and each pixel P includes a plurality of subpixels SP. At this time, the subpixels SP may include a red subpixel, a green subpixel, and a blue subpixel. In addition, the subpixels may further include a white subpixel.

The plurality of gate lines and data lines are arranged in the display region AA, and the subpixels SP are arranged at the crossing portions of the gate lines and the data lines. In each subpixel SP, a thin film transistor which is a switching element, and a display element for implementing an actual image are arranged.

The display element may include one of various display elements. For example, the display element may be an organic light emitting display element, a liquid crystal display element, a quantum dot display element, a micro LED display element, or a mini LED display element.

The gate driving portion and the data driving portion that apply various signals to the subpixel SP may be arranged in the non-display region NA. The gate driving portion applies the scan signal to the subpixel SP through the gate line, and the data driving portion applies an image signal to the subpixel SP through the data line.

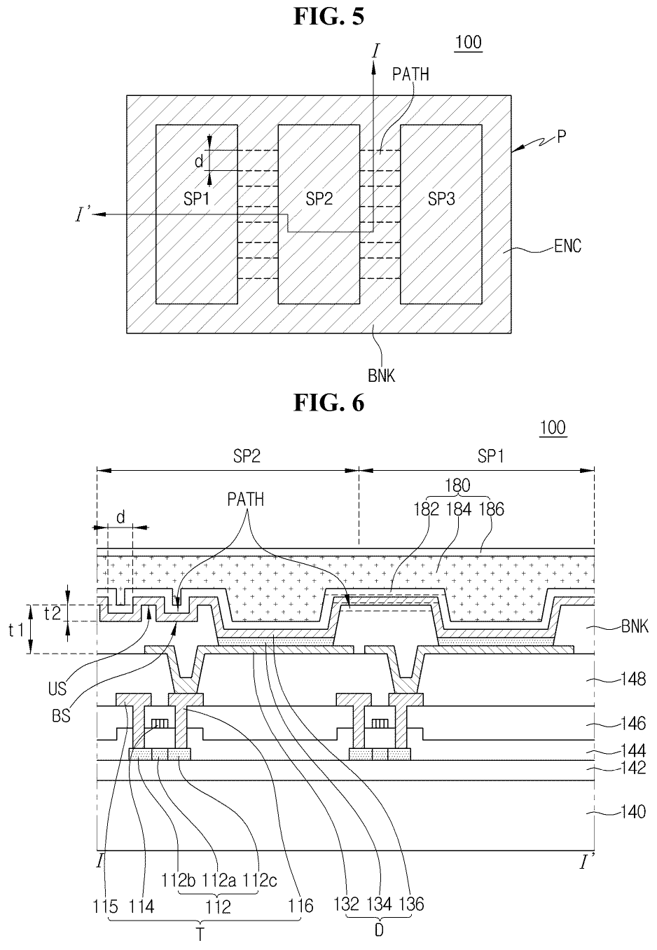

FIG. 5 is a plan view schematically illustrating a structure of a pixel of a display apparatus according to the present disclosure.

As illustrated in FIG. 5, the pixel P of the display apparatus 100 according to the present disclosure includes first to third subpixels SP1 to SP3.

At this time, the first to third subpixels SP1 to SP3 may each be formed in a rectangular shape and arranged within the pixel P. In the drawing, the first to third subpixels SP1 to SP3 are formed with the same area, but the first to third subpixels SP1 to SP3 may be formed with different areas.

In addition, the first to third subpixels SP1 to SP3 may be formed in various shapes. For example, the first to third subpixels SP1 to SP3 may each be formed in a rhombus shape, a pentagon shape, a hexagon shape, a triangle shape, or a circular shape or an oval shape. In addition, the first to third subpixels SP1 to SP3 may be formed in different shapes.

The first to third subpixels SP1 to SP3 may be different ones of red subpixel, green subpixel, and blue subpixel, but not limited thereto. In addition, the pixel P may include a white subpixel.

A thin film transistor and an organic light emitting element are arranged in each of the first to third subpixels SP1 to SP3, and an encapsulation layer ENC is disposed thereon to block external moisture or oxygen from penetrating into the organic light emitting element. At this time, the encapsulation layer ENC may be formed over the entire display apparatus 100.

A bank layer BNK is formed along a perimeter (or boundary) of each of the subpixel SP1 to SP3 around each of the subpixels SP1 to SP3. For example, the bank layer BNK actually defines each of the subpixels SP1 to SP3.

At least one groove PATH is formed in the bank layer BNK between the subpixels SP1 to SP3. The groove PATH is formed by removing the bank layer BNK from an upper surface US (or top surface) to a set depth. The groove PATH may be a kind of waterway formed along the entire bank layer BNK between adjacent subpixels SP1 to SP3 to connect the adjacent subpixels SP1 to SP3 to each other. For example, the groove PATH may extend from an end of the bank layer BNK adjacent to one of two adjacent subpixels to another end of the bank layer BNK adjacent to another one of the two adjacent subpixels. As shown in FIG. 5, the groove PATH may extend from an end of the bank layer BNK adjacent to subpixel SP1 to another end of the bank layer BNK adjacent to subpixel SP2.

When an organic material for encapsulation is dropped on set dropping regions (or loading regions) to form the encapsulation layer ENC, the dropped organic material spreads and is coated on the entire display apparatus 100. The groove PATH acts as a passage through which the organic material flows when it spreads. Generally, the bank layer BNK is formed to a greater height than other regions and has a form that protrudes upward from a surface of the display apparatus 100. This protruding form is arranged in a matrix shape over the entire display apparatus 100.

Therefore, when the organic material spreads, the bank layer BNK acts as a barrier that blocks flow of the organic material. Since the groove PATH is formed at a depth set in the bank layer BNK, a bottom surface BS of the groove PATH is formed at a position lower than the upper surface US of the bank layer BNK. Thus, the organic material whose flow is blocked by the bank layer BNK flows through the groove PATH and spreads throughout the display apparatus 100.

In the drawing, the groove PATH is formed in a number set in the bank layer BNK between the subpixels SP1 to SP3 (for example, 4 grooves PATH), but the groove PATH is not formed in this specific number. For example, the groove PATH may be formed in various numbers depending on a viscosity of the organic material, height and material of the bank layer BNK, a number of dropping regions, an area of the display apparatus 100, area and shape of the subpixels SP1 to SP3, etc.

In addition, a width d of the groove PATH can be formed to various values depending on a viscosity of the organic material, height and material of the bank layer BNK, a number of dropping regions, an area of the display apparatus 100, area and shape of the subpixels SP1 to SP3, a number of the grooves PATH, etc.

Hereinafter, a specific structure of the display apparatus 100 according to embodiments of the present disclosure is described in detail with reference to the attached drawings.

FIG. 6 is a cross-sectional view taken along a line I-I′ of FIG. 5, which specifically illustrates a display apparatus according to a first embodiment of the present disclosure. The display apparatus 100 according to the first embodiment of the present disclosure is configured with the first to third subpixels SP1 to SP3 that display different colors, but since the first to third subpixels SP1 to SP3 are formed with substantially the same structure, only two adjacent subpixels SP1 and SP2 are illustrated for convenience of explanation.

As illustrated in FIG. 6, a buffer layer 142 is formed on a substrate 140. The substrate 140 may be formed of a rigid material such as glass or a flexible plastic material.

When the substrate 140 is formed of a plastic material, the substrate 140 may be formed of at least one of polyimide, polymethylmethacrylate, polyethylene terephthalate, polyethersulfone, and polycarbonate, but not limited thereto.

For example, when the substrate 140 is formed of polyimide, it may be configured with a plurality of polyimide layers, and an inorganic layer may be further disposed between the polyimide layers, but not limited thereto.

The buffer layer 142 may improve adhesive strength between layers formed on the substrate 140 and the substrate 140, and block alkaline components, etc., that leak from the substrate 140. In addition, the buffer layer 142 may delay diffusion of moisture or oxygen that has penetrated the substrate 140.

The buffer layer 142 may be formed of a single layer of SiNx or SiOx, or multiple layers using at least one of SiNx and SiOx. When the buffer layer 142 is formed of the multiple layers, SiOx and SiNx may be formed alternately. The buffer layer 142 may be omitted based on type and material of the substrate 140, structure and type of a thin film transistor T, etc.

The thin film transistor T is formed on the buffer layer 142 of each of the subpixels SP1 and SP2. For convenience of explanation, only a driving thin film transistor among various thin film transistors that may be arranged in the display region AA is illustrated, but other thin film transistor such as a switching thin film transistor may also be included in each of the subpixels SP1 and SP2. In addition, although the thin film transistor T is illustrated as having a top gate structure in the drawing, it is not limited to this structure and may be implemented with other structure such as a bottom gate structure.

The thin film transistor T includes a semiconductor layer 112 disposed on the buffer layer 142, a gate insulating layer 144 formed on the semiconductor layer 112, a gate electrode 114 disposed on the gate insulating layer 144, an interlayered insulating layer 146 formed on the gate electrode 114, and a source electrode 115 and a drain electrode 116 disposed on the interlayered insulating layer 146.

The semiconductor layer 112 may be formed of a polycrystalline semiconductor. For example, the polycrystalline semiconductor may be formed of low temperature polysilicon (LTPS) with high mobility, but not limited thereto.

In addition, the semiconductor layer 112 may be formed of an oxide semiconductor. For example, it may be formed of one of IGZO (indium-gallium-zinc-oxide), IZO (indium-zinc-oxide), IGTO (indium-gallium-tin-oxide), and IGO (indium-gallium-oxide), but not limited thereto. In another example, the oxide semiconductor may include a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto. The semiconductor layer 112 includes a channel region 112a in a central region and a source region 112b and a drain region 112c as doping regions on both sides.

The gate insulating layer 144 may be formed of a single layer or multiple layers using an inorganic material such as SiOx and/or SiNx, but not limited thereto. The interlayered insulating layer 146 may be formed of a single layer or multiple layers using an organic material such as photoacrylic or an inorganic material such as SiNx or SiOx. In addition, the interlayered insulating layer 146 may be formed of multiple layers including organic and inorganic layers, but not limited thereto.

The source electrode 115 and the drain electrode 116 may be formed of a single layer or multiple layers using at least one of molybdenum (Mo), aluminum (Al), chromium (Cr), gold (Au), titanium (Ti), nickel (Ni), neodymium (Nd), copper (Cu), and an alloy thereof, but not limited thereto. The source electrode 115 and the drain electrode 116 can contact the source region 112b and the drain region 112c of the semiconductor layer 112 through contact holes formed in the gate insulating layer 144 and the interlayered insulating layer 146, respectively.

A bottom shield metal layer may be arranged on the substrate 140 and below the semiconductor layer 112. The bottom shield metal layer may minimize or reduce back channel phenomenon caused by charges trapped in the substrate 140 and prevent or reduce afterimages or performance degradation of transistor, and may be formed of a single layer or multiple layers using titanium (Ti), molybdenum (Mo), and/or an alloy thereof, but not limited thereto.

A planarization layer 148 is formed over the substrate 140 on which the thin film transistor T is formed. The planarization layer 148 may be configured to protect the thin film transistor and to planarize a step caused due to the thin film transistor. The planarization layer 148 may be formed of an organic material such as photoacrylic, but not limited thereto, and may be formed of multiple layers including an inorganic layer and an organic layer.

A light emitting element D is arranged on the planarization layer 148 in the display region AA. The light emitting element D includes a first electrode 132, a light emitting layer 134, and a second electrode 136.

The first electrode 132 is disposed on the planarization layer 148 and is electrically connected to the drain electrode 116 of the thin film transistor T through a contact hole formed in the planarization layer 148. The first electrode 132 may be formed of at least one of silver (Ag), aluminum (Al), gold (Au), molybdenum (Mo), tungsten (W), chromium (Cr), and an alloy thereof. In addition, the first electrode 132 may be formed of a transparent metal oxide layer such as ITO (indium tin oxide) or IZO (indium zinc oxide).

When the display apparatus 100 is a top emission type display apparatus, the first electrode 132 may include an opaque conductive material to function as a reflective electrode that reflects light. When the display apparatus 100 is a bottom emission display apparatus, the first electrode 132 may be formed using a transparent conductive material that transmits light, such as ITO (indium tin oxide) or IZO (indium zinc oxide).

The bank layer BNK is formed at a boundary of each subpixel on the planarization layer 148. The bank layer BNK may be a kind of partition wall that defines the subpixel. The bank layer BNK may define each subpixel and prevent or reduce light of specific colors output from adjacent subpixels from being mixed and output.

The bank layer BNK may be formed of at least one of an inorganic insulating material such as SiNx or SiOx, an organic insulating material such as BCB (BenzoCycloButene), an acrylic resin, an epoxy resin, a phenolic resin, a polyamide resin, or a polyimide resin, and a photosensitive material including a black pigment, but not limited thereto.

The groove PATH is formed at the upper surface US of the bank layer BNK. Since the groove PATH is formed with a depth t2 smaller than a total thickness t1 of the bank layer BNK (i.e., t1>t2), the groove PATH is formed in a concave shape from the upper surface US of the bank layer BNK and can serve as a path or channel for an organic material to flow between subpixels SP1 and SP2.

The depth t2 and width d of the groove PATH can be designed variously depending on a viscosity of the organic material, height and material of the bank layer BNK, a number of dropping regions, an area of the display apparatus 100, area and shape of the subpixels, and a number of the grooves PATH. In one embodiment, the passage (e.g., groove PATH) is formed at a selected depth (e.g., t2) from the upper surface of the bank layer.

The light emitting layer 134 may be formed on an upper surface of the first electrode 132 of each of the subpixels SP1 and SP2, and on a part of an inclined surface of the bank layer BNK.

The light emitting layers 134 may include an R light emitting layer that is formed in a red subpixel and emits red light, a G light emitting layer that is formed in a green subpixel and emits green light, and a B light emitting layer that is formed in a blue subpixel and emits blue light. The light emitting layer 134 may include an organic light emitting layer, or an inorganic light emitting layer, for example, a nano-sized material layer, a quantum dot light emitting layer, a micro LED light emitting layer, or a mini LED light emitting layer, but not limited thereto.

The light emitting layer 134 may include not only an organic light emitting layer, but also an electron injection layer and a hole injection layer that inject electrons and holes into the organic light emitting layer, and an electron transport layer, a hole blocking layer, an electron blocking layer, and a hole transport layer that transport the injected electrons and holes into the organic light emitting layer, but not limited thereto.

The second electrode 136 is disposed on the light emitting layer 134 and may be formed of a single layer or multiple layers using a metal and/or an alloy thereof. In addition, the second electrode 136 may be formed of a transparent metal oxide such as ITO (indium tin oxide) or IZO (indium zinc oxide), but not limited thereto.

When the display apparatus 100 is a top emission type, the second electrode 136 may be formed using a semitransparent conductive material that transmits light. For example, the second electrode 136 may be formed using at least one of alloys such as LiF/Al, CsF/Al, Mg:Ag, Ca/Ag, Ca:Ag, LiF/Mg:Ag, LiF/Ca/Ag, and LiF/Ca:Ag.

When the display apparatus 100 is a bottom emission type, the second electrode 136 may be formed using an opaque conductive material as a reflective electrode that reflects light. For example, the second electrode 136 may be formed using at least one of silver (Ag), aluminum (Al), gold (Au), molybdenum (Mo), tungsten (W), chromium (Cr), and an alloy thereof.

In addition, the light emitting element D may be configured in a tandem structure.

The tandem structure includes a plurality of light emitting layers, and a charge generation layer may be disposed between the light emitting layers. The charge generation layer is for controlling charge balance between the plurality of light emitting layers, and may be configured in a plurality of layers including a first charge generation layer and a second charge generation layer. The charge generation layer may include an N-type charge generation layer and a P-type charge generation layer, and may be formed of a light emitting layer doped with an alkali metal such as lithium (Li), sodium (Na), potassium (K) and cesium (Cs) or an alkali earth metal such as magnesium (Mg), strontium (Sr), barium (Ba) and radium (Ra), but not limited thereto.

An encapsulating layer 180 is formed on the light emitting element D to encapsulate the light emitting element D. If the light emitting element D is exposed to moisture or oxygen, a pixel shrinkage phenomenon in which a light emission region is reduced or a defect in which a dark spot is formed in a light emission region may occur. In addition, moisture or oxygen oxidizes an electrode made of metal. The encapsulation layer 180 blocks or reduces penetration of moisture and oxygen from an outside, thereby preventing or reducing the light emitting element D and various electrodes from being defective.

The encapsulation layer 180 may be configured with a first encapsulation layer 182, a second encapsulation layer 184, and a third encapsulation layer 186, but not limited thereto, and may be configured two layers, or four or more layers.

The first encapsulation layer 182 and the third encapsulation layer 186 may be formed of a single layer or multiple layers including one or more of inorganic materials such as SiOx, SiON, SiNx, etc., and may further include an organic material between the inorganic material layers, but not limited thereto. The second encapsulation layer 184 may be formed of an organic insulating material such as acrylic resin, epoxy resin, polyimide, polyethylene, or silicon oxycarbon (SiOC), but not limited thereto. The third encapsulation layer 186 may be formed of a thin metal (e.g., face seal metal), but not limited thereto.

A touch member may be formed. The touch member may be arranged in the display region AA to detect a touch input. The touch member may detect external touch information using a user's finger, a touch pen, etc.

As described above, in the display apparatus 100 of this embodiment, following effects can be obtained by forming the groove PATH at the upper surface of the bank layer BNK that is between the subpixels SP1 and SP2 and divides the subpixels SP1 and SP2.

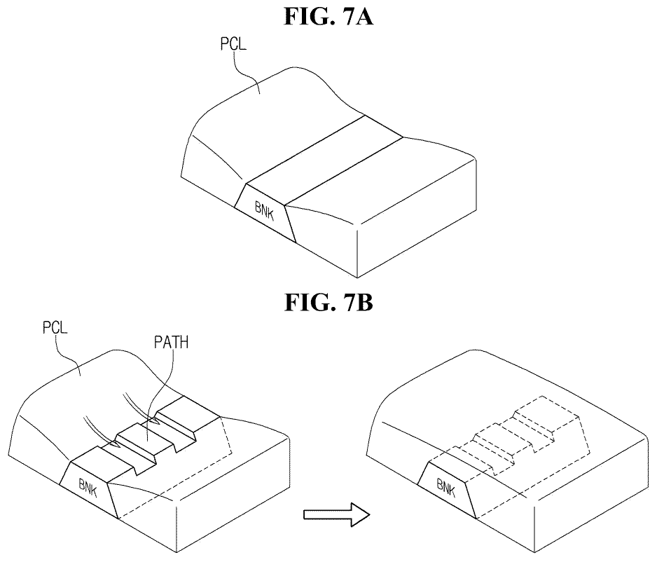

FIG. 7A and FIG. 7B are view illustrating that an organic material for encapsulation spreads beyond a bank layer BNK without a groove formed at an upper surface and a bank layer with a groove formed at an upper surface, respectively.

As shown in FIG. 7A, an organic material PCL for encapsulation dropped on set regions spreads outward from the dropping region. At this time, the dropping regions can be set in various regions. For example, the dropping regions can be formed in central regions of the display apparatus 100 or can be formed in various regions throughout the display apparatus 100. The dropping region can be set in various ways depending on an area of the display apparatus 100, a viscosity of the organic material PCL, a structure of the display apparatus 100, etc.

The organic material PCL dropped on the dropping regions spreads isotropically outward. Since a relatively tall structure is not arranged in the subpixels SP1 and SP2 surrounded by the bank layer BNK, the organic material PCL flows smoothly. However, at the boundary regions of the subpixels SP1 and SP2, the flow of the organic material PCL is blocked by the bank layer BNK as the tall structure.

Of course, the organic material PCL flows over the bank layer BNK to the adjacent subpixels SP1 and SP2, but some of the organic material PCL is blocked by the bank layer BNK. In addition, since the flow speed of the organic material PCL is reduced by the bank layer BNK, some of the organic material PCL does not reach set regions (for example, regions where the dropped organic material PCL is to be coated).

Therefore, since the organic material PCL is not coated uniformly over the entire display apparatus 100, an encapsulation layer is not formed with a uniform thickness. Furthermore, the organic material PCL is not coated on some regions. Such uneven thickness of the encapsulation layer and/or lack of filling of the encapsulation layer not only causes distortion of light output to an outside, which causes poor image quality such as spots, but also causes deterioration of an organic light emitting element due to moisture or oxygen penetrating into the unfilled region.

As shown in FIG. 7B, in the display apparatus 100 according to the first embodiment of the present disclosure, the grooves PATH are formed along the flow direction of the organic material PCL at the upper surface of the bank layer BNK, thereby forming a flow passage or flow path of the organic material PCL, so that the organic material PCL blocked by the bank layer BNK flows through the grooves PATH. Of course, the organic material PCL does not spread only through the grooves PATH, but also spreads beyond the bank layer BNK.

As such, in the display apparatus 100 according to the present disclosure, since the groove PATH is formed at the upper surface of the bank layer BNK, it is possible to prevent or reduce a portion of the organic material PCL from being blocked by the bank layer BNK or the flow speed of the organic material PCL from being reduced, thereby preventing or reducing uneven thickness of the encapsulation layer and/or lack of filling of the encapsulation layer. As a result, spots due to defects in the encapsulation layer can be prevented or reduced, and deterioration due to penetration of moisture or oxygen can be prevented or reduced.

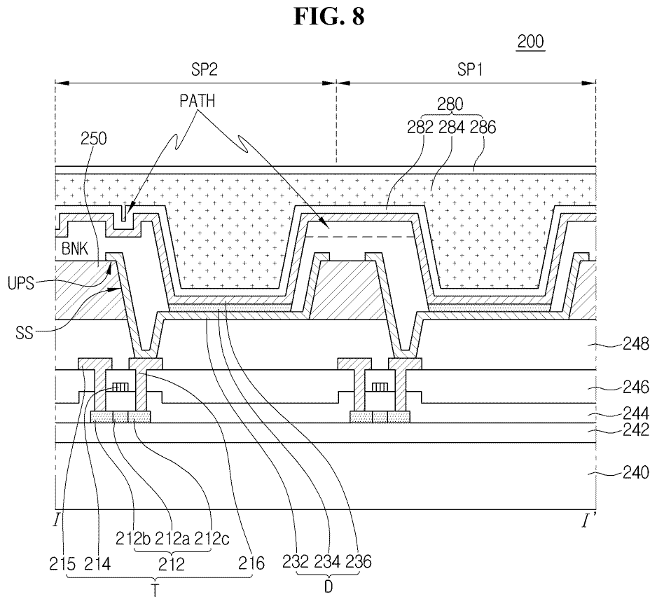

FIG. 8 is a cross-sectional view illustrating a structure of a display apparatus according to a second embodiment of the present disclosure. Description of the same structure as the display apparatus 100 of the first embodiment illustrated in FIG. 6 is omitted or simplified, and different structures are described in detail.

As illustrated in FIG. 8, a thin film transistor T and a light emitting element D are formed in each of the subpixels SP1 and SP2 on a substrate 240, and an encapsulation layer 280 including a first encapsulation layer 282 formed of an inorganic material, a second encapsulation layer 284 formed of an organic material, and a third encapsulation layer 286 formed of an inorganic material is formed on the light emitting element D to encapsulate the light emitting element D.

The thin film transistor T includes a semiconductor layer 212 disposed on a buffer layer 242, a gate electrode 214 disposed on a gate insulating layer 244, a source electrode 215 and a drain electrode 216 disposed on an interlayered insulating layer 246.

An insulating pattern 250 is formed between the subpixels SP1 and SP2. The insulating pattern 250 may be formed of at least one of an inorganic insulating material such as SiNx or SiOx, an organic insulating material such as BCB (BenzoCycloButene), an acrylic resin, an epoxy resin, a phenolic resin, a polyamide resin, or a polyimide resin, and a photosensitive material including a black pigment, but not limited thereto.

The light emitting element D is disposed in each of the subpixels SP1 and SP2 between the insulating patterns 250. The light emitting element D includes a first electrode 232, a light emitting layer 234, and a second electrode 236. The first electrode 232 may be an anode electrode, and the second electrode 236 may be a cathode electrode. The first electrode 232 is disposed on the planarization layer 248 of each of the subpixels SP1 and SP2 and extends to a side surface SS and at least a portion of an upper surface UPS of the insulating pattern 250. At this time, since the side surface SS of the insulating pattern 250 forms a tapered inclined surface, the first electrode 232 formed on the side surface SS of the insulating pattern 250 also forms a tapered inclined surface.

A bank layer BNK is formed on the insulating pattern 250. Since the bank layer BNK is formed with a wider width than the insulating pattern 250, it completely covers the first electrode 232 disposed on the side surface SS and upper surface UPS of the insulating pattern 250. The bank layer BNK may be formed of the same material as the insulating pattern 250 or may be formed of a different material from the insulating pattern 250.

The light emitting layer 234 is disposed on the first electrode 232 of each of the subpixels SP1 and SP2 surrounded by the bank layer BNK, and the second electrode 236 is disposed on the light emitting layer 234. At this time, the second electrode 236 is formed on the entire surface of the display apparatus 200. For example, the second electrode 236 extends from over the first electrodes 232 of the subpixels SP1 and SP2 to the side surface and the upper surface of the bank layer BNK.

As such, in this embodiment, the insulating pattern 250 and the bank layer BNK are provided, and the first electrode 232 is formed on the side surface and at least a portion of the upper surface of the insulating pattern 250, and the second electrode 236 is formed on the side surface and the upper surface of the bank layer BNK, thereby improving light efficiency. This is described in detail below.

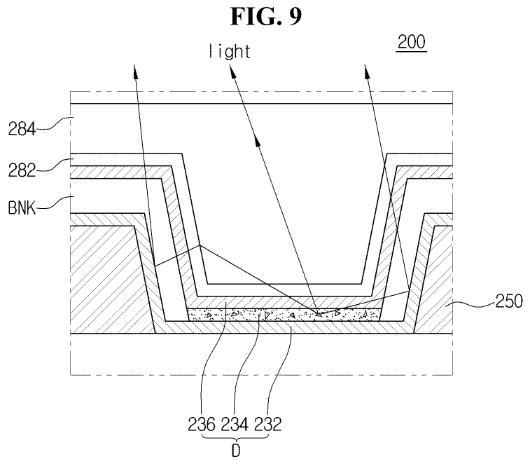

As illustrated in FIG. 9, the first electrode 232, the light emitting layer 234, and the second electrode 236 are sequentially laminated in the subpixel surrounded by the insulating pattern 250 to form the light emitting element D that emits light.

At this time, the first electrode 232 is formed on the side surface and the upper surface of the insulating pattern 250, and the second electrode 236 is formed on the side surface and the upper surface of the bank layer BNK. Thus, the bank layer BNK which is an insulating material is placed between the first electrode 232 and the second electrode 236 over the insulating pattern 250 between the subpixels to electrically insulate the first electrode 232 and the second electrode 236.

Therefore, light is emitted only from the light emitting layer 234 of the subpixel surrounded by the insulating pattern 250.

The first electrode 232 is formed of a metal having good reflectivity. Therefore, light emitted from the light emitting layer 234 and input to the side surface of the insulating pattern 250 is reflected from the first electrode 232 on the side surface of the insulating pattern 250 and output upward.

The display apparatus 200 of this embodiment is a top emission type display apparatus.

In the case of the top emission display apparatus 100 according to the first embodiment of the present disclosure, since the first electrode 132 is disposed on a plane below the light emitting layer 234, light emitted from the light emitting layer 134 and output at an angle set relative to a front is absorbed by the bank layer BNK and not output to the outside.

On the other hand, in the display apparatus 200 of this embodiment, since the side surface of the insulating pattern 250 protrudes above the light emitting layer 234 and forms an inclined surface of a set angle (for example, an angle in a range from 20° to 90°), light emitted from the light emitting layer 234 at a certain angle relative to the front is reflected by the first electrode 232 on the side surface of the insulating pattern 250 and outputted upward.

For example, in the display apparatus 100 of the first embodiment, light output at a certain angle relative to the front is absorbed inside the display apparatus 100, whereas in the display apparatus 200 of this embodiment, light output at a certain angle relative to the front is reflected by the first electrode 232 and output. Thus, light extraction efficiency of the display apparatus 200 of this embodiment is significantly improved compared to the display apparatus 100 of the first embodiment.

Referring again to FIG. 8, at least one groove PATH is formed at the upper surface of the bank layer BNK between adjacent subpixels SP1 and SP2. The groove PATH is formed in a concave shape from the upper surface of the bank layer BNK and can serve as a passage or waterway for an organic material to flow between the subpixels SP1 and SP2.

In the display apparatus 200 of this embodiment, the bank layer BNK is formed on the insulating pattern 250 to completely cover the insulating pattern 250. Thus, compared to the display apparatus 100 of the first embodiment in which only the bank layer BNK is provided, a height of the structure from the subpixels SP1 and SP2, for example, a height of the insulating pattern 250 and the bank layer BNK, is much greater.

Therefore, when coating the organic material for forming the second encapsulation layer 284, the flow of the organic material is blocked by the high structure of the insulating pattern 250 and the bank layer BNK, and thus, the organic material is not coated on some regions of the display apparatus 200.

However, as in the display apparatus 200 of this embodiment, since the groove PATH is formed at the upper surface of the bank layer BNK, a passage or channel through which the organic material flows is created between the adjacent subpixels SP1 and SP2. Therefore, the organic material that was blocked by the high structure of the insulating pattern 250 and the bank layer BNK flows through the groove PATH, so that the organic material can be coated uniformly over the entire display apparatus 200.

In addition, in the display apparatus 200 of this embodiment, the two-layered structure (with the insulating pattern 250 and the bank layer BNK) surrounds the subpixels SP1 and SP2, and the light emitting element D is placed between the structures. In this respect, the lower insulating pattern 250 may be referred to as a first bank layer, and the upper bank layer BNK may be referred to as a second bank layer.

As described above, in the present disclosure, by forming a passage, through which the organic material flows, in the bank layer between adjacent subpixels, it is possible to form the encapsulation layer of uniform thickness, and as a result, it is possible to prevent or reduce defects such as spots caused by an encapsulation layer of uneven thickness.

In addition, in the present disclosure, the two-layered bank layer is formed, and the first electrode of metal is formed on the inclined side surface of the lower first bank layer, so that light emitted from the light emitting layer and incident in the lateral direction of the light emitting element is reflected by the first electrode and output to the front, thereby improving the light efficiency of the display apparatus.

In addition, in the present disclosure, since it is possible to manufacture a high-efficiency display apparatus by improving the light efficiency, power consumption can be reduced and low power operation is possible.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a plurality of subpixels;
a bank layer arranged to surround each of the plurality of subpixels;
a light emitting element disposed in the subpixel;
an encapsulation layer encapsulating the light emitting element; and
at least one passage formed at an upper surface of the bank layer between adjacent subpixels,
wherein, in operation, an organic material for forming the encapsulation layer flows through the at least one passage between the adjacent subpixels.

2. The display apparatus of claim 1, wherein the light emitting element includes:
a first electrode having a portion of an end disposed below the bank layer;
a light emitting layer on the first electrode of the subpixel;
a second electrode on the light emitting layer, and a side surface and an upper surface of the bank layer.

3. The display apparatus of claim 1, wherein the at least one passage is formed at a selected depth from the upper surface of the bank layer.

4. The display apparatus of claim 1, wherein the bank layer includes:
a first bank layer disposed between the adjacent subpixels; and
a second bank layer on the first bank layer.

5. The display apparatus of claim 4, wherein the light emitting element includes:
a first electrode over the substrate surrounded by the first bank layer and extending to a side surface and at least a portion of an upper surface of the first bank layer;
a light emitting layer on the first electrode in the subpixel;
a second electrode on the light emitting layer and extending to a side surface and an upper surface of the second bank layer.

6. The display apparatus of claim 5, wherein the at least one passage is a groove formed at a selected depth at the upper surface of the second bank layer.

7. The display apparatus of claim 5, wherein the side surface of the first bank layer is a tapered inclined surface.

8. The display apparatus of claim 5, wherein the second bank layer covers the first electrode disposed on the side surface and at least a portion of the upper surface of the first bank layer.

9. The display apparatus of claim 5, wherein the side surface of the first bank layer protrudes above the light emitting layer to form an inclined surface of a predetermined angle.

10. The display apparatus of claim 7, wherein the first electrode includes metal.

11. The display apparatus of claim 4, wherein the first bank layer includes at least one of an inorganic material, an organic material, and a photosensitive material including pigments.

12. The display apparatus of claim 4, wherein the second bank layer includes the same material as the first bank layer.

13. The display apparatus of claim 4, wherein the second bank layer includes a material different from the first bank layer.

14. The display apparatus of claim 1, wherein the passage is formed in a concave shape from the upper surface of the bank layer.

15. The display apparatus of claim 1, wherein a bottom surface of the passage is lower than the upper surface of the bank layer.

16. A display apparatus comprising:
a substrate including a plurality of subpixels;
a bank layer disposed between the plurality of subpixels;
a light emitting element disposed in each of the plurality of subpixels;
an encapsulation layer encapsulating the light emitting element; and
at least one groove formed at an upper surface of the bank layer between adjacent subpixels.

17. The display apparatus of claim 16, wherein the encapsulation layer is formed in the at least one groove.

18. The display apparatus of claim 16, wherein the at least one groove is formed along the entire bank layer between the adjacent subpixels.
